(19) United States
(12) Patent Application Publication
(10) Pub. No.: US 2026/0047432 A1
(43) Pub. Date: Feb. 12, 2026

(54) LOW WARPAGE CHIP

(71) Applicant: POWERTECH TECHNOLOGY INC., Hsinchu County (TW)

(72) Inventor: Ching-Chao LIN, Hsinchu County (TW)

(73) Assignee: POWERTECH TECHNOLOGY INC., Hsinchu County (TW)

(21) Appl. No.: 19/245,400

(22) Filed: Jun. 23, 2025

(30) Foreign Application Priority Data
Aug. 9, 2024 (TW) 113129920

(51) Int. Cl. H01L 23/373; H01L 21/56; H01L 23/00

(52) U.S. Cl. CPC H01L 23/373; H01L 21/56; H01L 24/14; H01L 2224/14132; H01L 2924/3511

(57) ABSTRACT

A low warpage chip includes a chip body, a plurality of signal contacts, and an anti-warpage layer. The chip body has a back surface and an active surface opposite to each other and has a circuit layer inside. The plurality of signal contacts are configured on the active surface and are electrically connected to the circuit layer. The anti-warpage layer covers at least a part of the back surface. A thermal expansion coefficient of the anti-warpage layer is greater than a thermal expansion coefficient of the chip body. When the low warpage chip undergoes a thermal processing procedure, the anti-warpage layer mitigates the warpage of the chip body to maintain the chip body in a relatively flat state.

### CROSS-REFERENCE TO RELATED APPLICATION(S)

This application claims the priority benefit of TW application serial No. 113129920 filed on Aug. 9, 2024, the entirety of which is hereby incorporated by reference herein and made a part of specification.

### BACKGROUND OF THE INVENTION

### 1. Field of the Invention

The present invention relates to a semiconductor chip, more particularly a low warpage chip that is able to greatly mitigate its warpage.

### 2. Description of the Related Art

In a technical field of a Multi-Chip Package (MCP) structure, when using a flip chip to include a plurality of chips for packaging, a thickness of each of the chips should be as thin as possible, so as to limit an overall thickness of a package with multiple layers of chips.

With reference to FIG. 13, a chip 200 typically includes a silicon layer 201, a circuit layer 202, and a plurality of signal contacts 203. The circuit layer 202 is typically composed of metallic materials for electrical conduction, and the circuit layer 202 is configured to electrically connect to the plurality of signal contacts 203. During manufacturing, the chip 200 is typically ground and polished, so as to decrease a thickness of the chip 200, thus allowing the chip to be thin enough for subsequent installation. As a result from the said grounding and polishing, a silicon layer thickness of the silicon layer 201 decreases, and as a circuit layer thickness of the circuit layer 202 remains unchanged, a ratio of the circuit layer thickness to the silicon layer thickness increases for the chip 200.

With reference to FIG. 14, during subsequent packaging steps, when the chip 200 is electrically connected to a circuit board P and the chip 200 undergoes a thermal processing procedure, since a thermal expansion coefficient of the circuit layer 202 and a thermal expansion coefficient of the silicon layer 201 differ, the chip 200 undergoing the thermal processing procedure would warp and manifest a warpage problem. The warpage problem leads to additional problems for the chip 200, such as causing the chip 200 to warp to uncontrollable heights and causing poor electrical connections between the chip 200 and the circuit board P. Evidently, the aforementioned technical problems leave much room for improvements for a currently existing chip.

### SUMMARY OF THE INVENTION

To overcome a warpage problem for a currently existing chip, the present invention provides a low warpage chip.

The low warpage chip of the present invention includes a chip body, a plurality of signal contacts, and an anti-warpage layer. The chip body has a back surface, an active surface, and a plurality of side surfaces. The back surface is facing an opposite direction from the active surface, and each of the side surfaces is respectively connecting the back surface and the active surface. A circuit layer is formed inside of the chip body. The plurality of signal contacts are configured on the active surface and are electrically connected to the circuit layer. The anti-warpage layer covers at least a part of the back surface, and the anti-warpage layer does not extend to the plurality of side surfaces of the chip body. A thermal expansion coefficient of the anti-warpage layer is greater than a thermal expansion coefficient of the chip body.

According to a location and a magnitude of a warpage of the chip body, the present invention configures the anti-warpage layer to adequately cover at least one location on the back surface of the chip body. Since the thermal expansion coefficient of the anti-warpage layer is greater than the thermal expansion coefficient of the chip body, when the low warpage chip experiences a thermal processing procedure, expansion and warpage of the anti-warpage layer are able to adequately compliment expansion and warpage of the chip body, and thus the anti-warpage layer is able to maintain the chip body in a relatively flat state and mitigate the warpage problem. As a result, a height of the low warpage chip can be more easily controlled for the thermal processing procedure, and when the low warpage chip is connected to a board, with the low warpage chip having greatly mitigated warpage, an electrical connection between the low warpage chip and the board can be better established.

### BRIEF DESCRIPTION OF THE DRAWINGS

FIG. 1 is an external perspective view of a low warpage chip in a first embodiment of the present invention.

FIG. 2 is a cross-sectional side-perspective view of the low warpage chip in the first embodiment of the present invention.

FIG. 3 is a top perspective view of the low warpage chip in the first embodiment of the present invention.

FIGS. 4A to 4D are perspective views for a flow chart for manufacturing the low warpage chip in an embodiment of the present invention.

FIG. 5 is a perspective view of the low warpage chip in a second embodiment of the present invention.

FIGS. 6A and 6B are perspective views of the low warpage chip in a third embodiment of the present invention.

FIGS. 7A and 7B are perspective views of the low warpage chip in a fourth embodiment of the present invention.

FIG. 8 is a perspective view of the low warpage chip in a fifth embodiment of the present invention.

FIG. 9 is a perspective view of the low warpage chip in a sixth embodiment of the present invention.

FIGS. 10A to 10C are perspective views of the low warpage chip in a seventh embodiment of the present invention.

FIGS. 11A and 11B are perspective views of the low warpage chip in an eighth embodiment of the present invention.

FIG. 12 is a perspective view of the low warpage chip of the present invention being configured to mount on a board and connect to the board.

FIG. 13 is a perspective view of a currently existing chip.

FIG. 14 is a perspective view of the currently existing chip having a warpage problem.

### DETAILED DESCRIPTION OF THE INVENTION

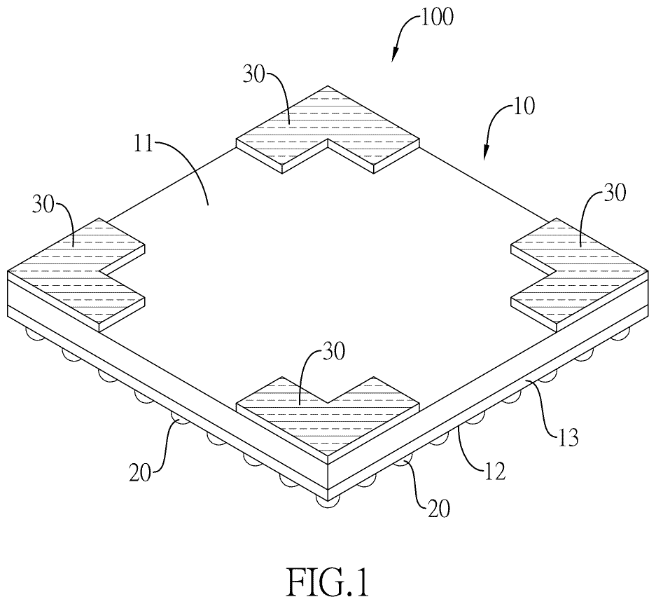

With reference to FIGS. 1 to 3, a low warpage chip 100 of the present invention in a first embodiment is shown. The low warpage chip 100 includes a chip body 10, a plurality of signal contacts 20, and an anti-warpage layer 30.

The chip body 10 includes two surfaces facing opposite directions and a plurality of side surfaces, and the two surfaces facing opposite directions are a back surface 11 and an active surface 12. Between the back surface 11 and the active surface 12 are the plurality of side surfaces, and each of the side surfaces is respectively connecting the back surface 11 and the active surface 12. The chip body 10 is manufactured by: preparing a base made of a semiconductor material, such as preparing a silicon base; and forming a circuit layer 13 with conductive metal within the base. In an embodiment, the circuit layer 13 is formed with copper as a redistribution layer (RDL) with multiple layers of redistribution structures.

The plurality of signal contacts 20 are mounted on the active surface 12 of the chip body 10. Each of the signal contacts 20 is made of a conductive material, and each of the signal contacts 20 is electrically connected to the circuit layer 13.

The anti-warpage layer 30 only partially covers the back surface 11 of the chip body 10, and the anti-warpage layer 30 does not extend to the side surfaces of the chip body 10 and does not cover the side surfaces of the chip body 10. A thermal expansion coefficient, or a coefficient of thermal expansion (CTE), of the anti-warpage layer 30 is greater than a thermal expansion coefficient of the chip body 10. In general, the greater a thermal expansion coefficient is, the greater a thermal expansion phenomenon may be observed, and thus a higher thermal expansion coefficient corresponds to a more pronounced thermal expansion phenomenon.

A placement location and a placement area of the anti-warpage layer 30 may be adjusted according to a warpage direction and a warpage magnitude of the chip body 10, thus allowing the anti-warpage layer 30 to mitigate a warpage of the chip body 10. As a result, despite the chip body 10 absorbing heat, the warpage of the chip body 10 is being complimented by the anti-warpage layer 30, thus keeping the chip body 10 in a relatively flat state and mitigate the warpage problem.

In a first embodiment, the anti-warpage layer 30 is placed at each corner of the back surface 11, and edges of the anti-warpage layer 30 are aligned with edges of the back surface 11. However, the anti-warpage layer 30 does not extend to the side surfaces of the chip body 10 and does not cover the side surfaces of the chip body 10.

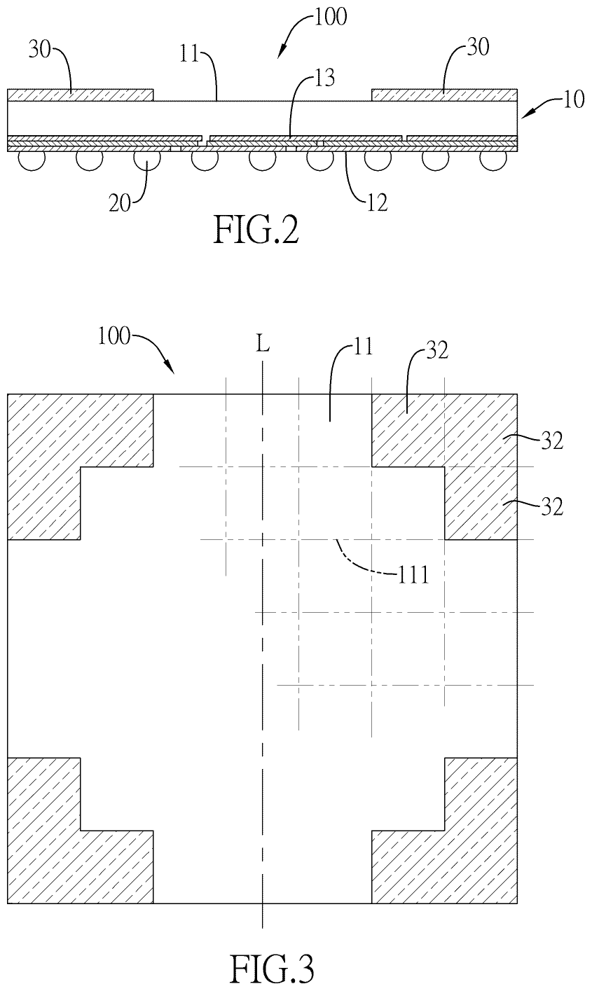

With reference to FIG. 3, the back surface 11 of the chip body 10 may be divided into a plurality of unit areas 111 of an equal size. By coating an insulating material over several of the unit areas 111, a plurality of coating blocks 32 of insulating material are formed for each of the several unit areas 111, and the plurality of coating blocks 32 collectively forms the anti-warpage layer 30. The anti-warpage layer 30 on the chip body 10 is symmetrically placed along two sides of a bisector line L. The bisector line L bisects the back surface 11 of the chip body 10 into two equally-sized areas. In FIG. 3, for example, two opposite edges of the back surface 11 respectively have a middle point, and the bisector line L intersects the two said middle points of the two opposite edges of the back surface 11. In another embodiment, the bisector line L may also be a diagonal line that intersects with two opposite corners of the back surface 11.

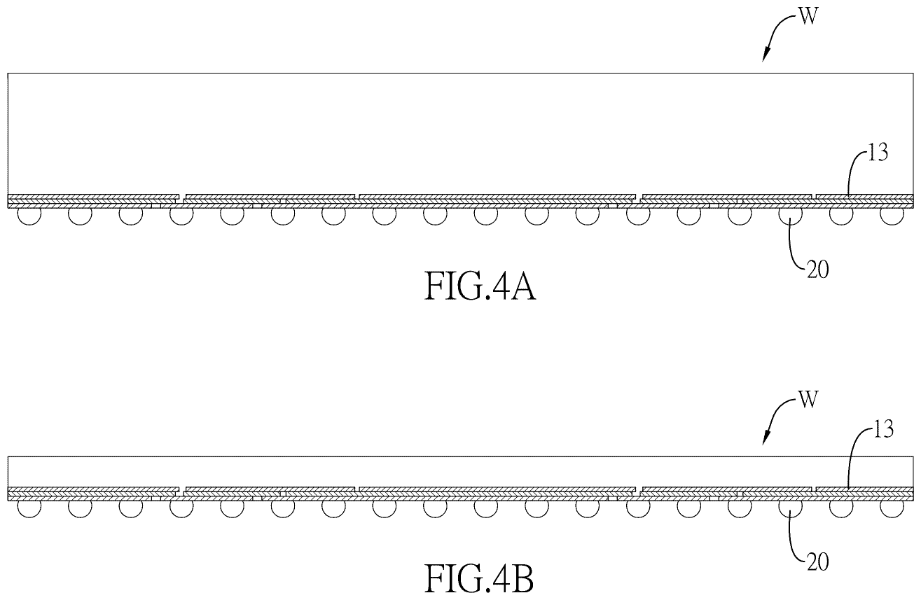

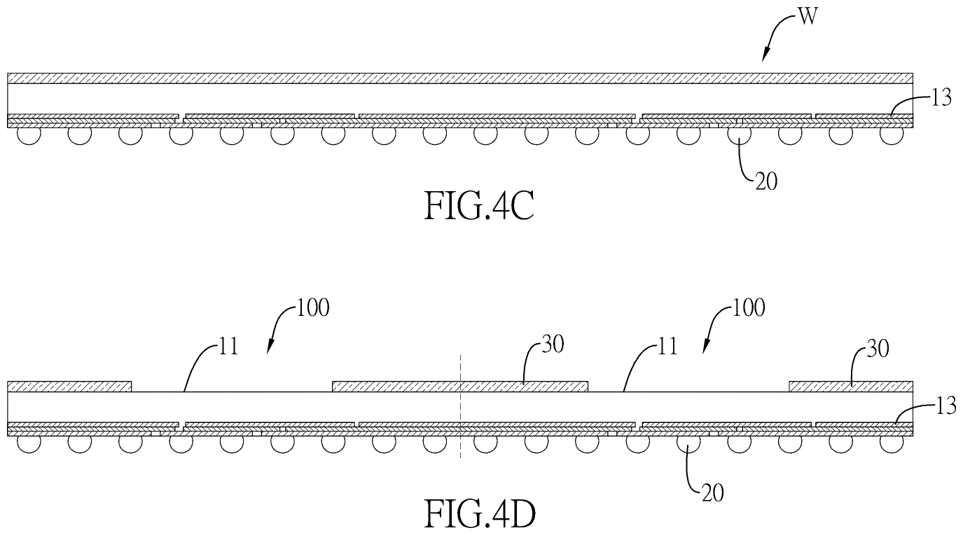

With reference to FIGS. 4A to 4D, an embodiment of a manufacturing method for the low warpage chip 100 of the present invention is shown.

With reference to FIG. 4A, a wafer W is prepared, wherein the wafer W had already completed forming a circuit layer 13 and a plurality of signal contacts 20.

With reference to FIG. 4B, a back surface of the wafer W is grounded and polished for decreasing a thickness of the wafer W, and thus the thickness of the wafer W is decreased to a target thickness.

With reference to FIG. 4C, one or more insulating layers are coated on the back surface of the wafer W, wherein the one or more insulating layers are made from one or more insulating materials, such as a combination of benzocyclobutene (BCB), polyimide (PI), and polybenzoxazole (PBO). Chemically similar insulating materials may also be used in the said combination. In an embodiment, the insulating materials are spin coated on the back surface of the wafer W. In other embodiments, the insulating materials may be screen printed on the back surface of the wafer W, or using other coating methods to coat the back surface of the wafer W.

With reference to FIG. 4D, the insulating materials are patternized for obtaining the anti-warpage layer 30. The wafer W is then diced (along the dotted line) into a plurality of low warpage chips 100. Each of the low warpage chips 100 has a back surface 11, and each of the low warpage chips 100 includes a portion of the anti-warpage layer 30 on the back surface 11. The anti-warpage layer 30 of each of the low warpage chips 100 is made of the said insulating materials.

Apart from the aforementioned first embodiment, the present invention may flexibly adjust a placement of the anti-warpage layer 30, according to a state of the warpage of the chip body 10, as presented below in another embodiment.

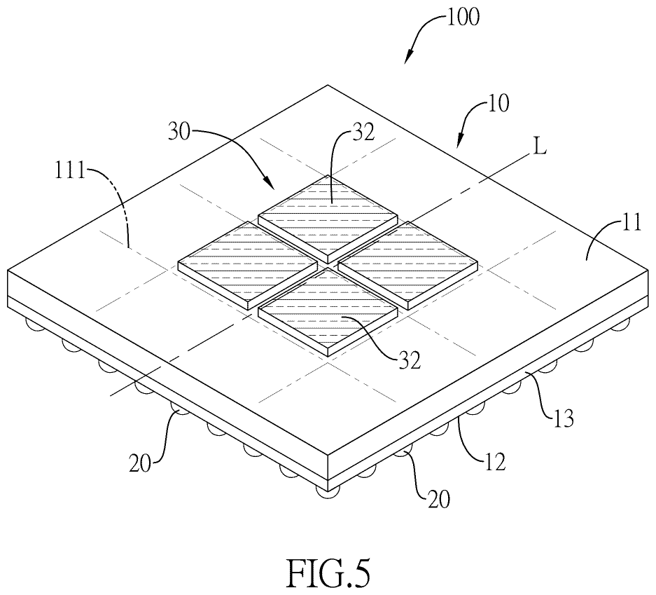

With reference to FIG. 5, the anti-warpage layer 30 includes a plurality of rectangular coating blocks 32. The plurality of rectangular coating blocks 32 are placed in a central area of the back surface 11, and the plurality of rectangular coating blocks 32 can be either separated from each other or connected to each other. In the present embodiment, the back surface 11 of the chip body 10 is divided into a plurality of unit areas 111 of a same size. Parts of the unit areas 111, that are away from the edges of the back surface 11, collectively form the central area of the back surface 11. In the present embodiment, the anti-warpage layer 30 is symmetrically placed along two sides of a bisector line L. In other embodiments, the plurality of rectangular coating blocks 32 are placed on parts of the unit areas 111 that are adjacent to the edges of the back surface 11. In other words, the plurality of rectangular coating blocks 32 are placed in peripheral areas of the back surface 11.

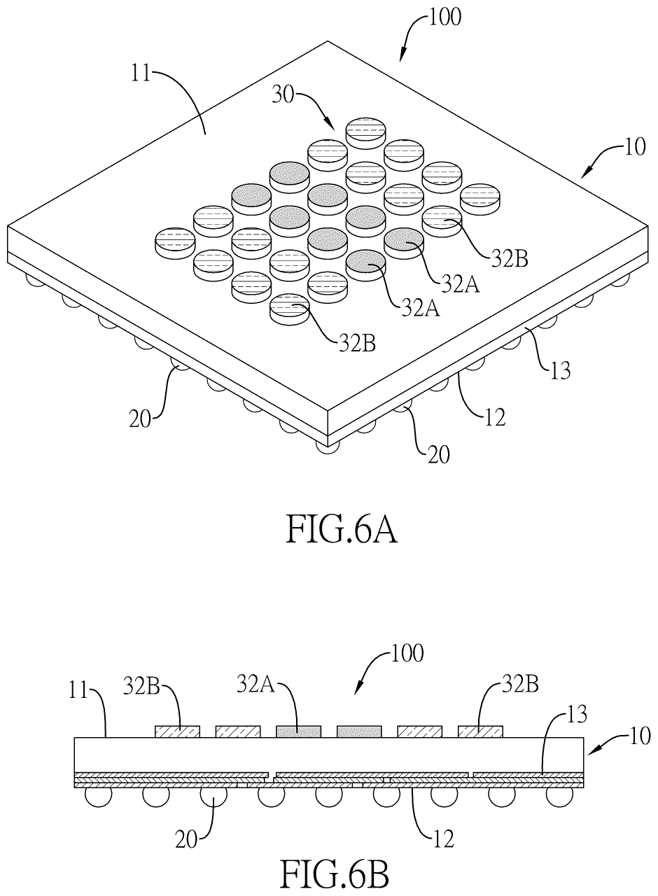

With reference to FIG. 6A and FIG. 6B, in a third embodiment of the present invention, the anti-warpage layer 30 includes the plurality of rectangular coating blocks 32 that are made of different materials. For instance, the central area of the back surface 11 is made of a plurality of first coating blocks 32A of a first insulating material, and besides the first coating blocks 32A are a plurality of second coating blocks 32B of a second insulating material. The first insulating material is different from the second insulating material, and hence the first insulating material has a thermal expansion coefficient different from a thermal expansion coefficient of the second insulating material. In the present embodiment, according to a magnitude difference between a warpage at a place on the chip body 10 and a warpage at another place on the same chip body 10, the present invention is able to form the anti-warpage layer 30 with different insulating materials on the same chip body 10, thus adequately mitigating the magnitudes of the warpage on the same chip body 10.

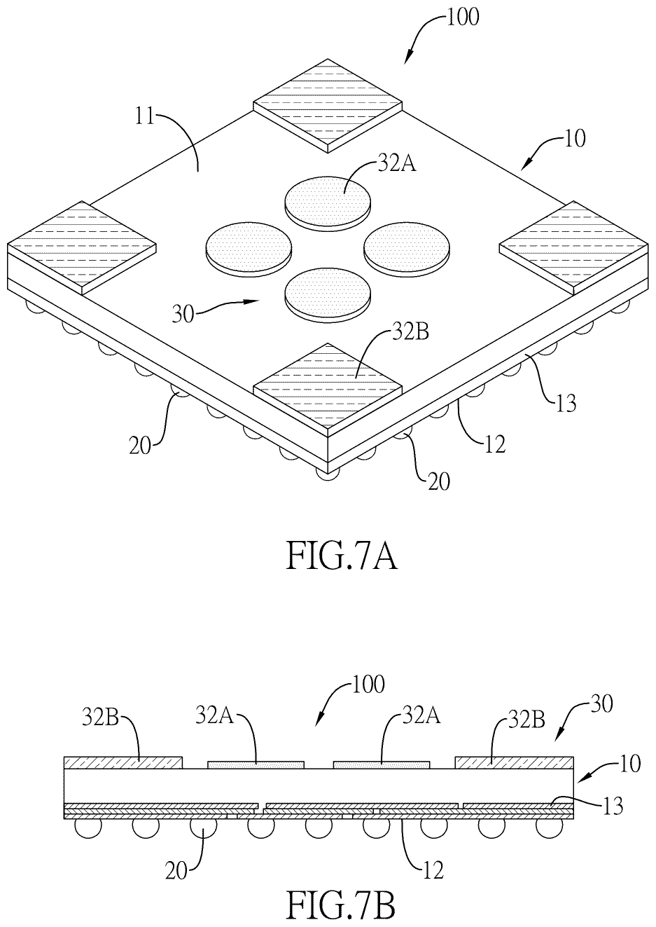

With reference to FIG. 7A and FIG. 7B, in a fourth embodiment of the present invention, the anti-warpage layer 30 includes a plurality of first coating blocks 32A and a plurality of second coating blocks 32B that are made of different materials. More particularly, the first coating blocks 32A are placed in the central area of the back surface 11, and the second coating blocks 32B are placed at the four corners of the back surface 11. The first coating blocks 32A are made from a first insulating material, the second coating blocks 32B made from a second insulating material, the first insulating material is different from the second insulating material, and thus the first insulating material has a different thermal expansion coefficient from the second insulating material. In the present embodiment, on the back surface 11, a thickness of each of the first coating blocks 32A is different from a thickness of each of the second coating blocks 32B. For example, the thickness of each of the first coating blocks 32A is less than the thickness of each of the second coating blocks 32B. Furthermore, the first coating blocks 32A are shaped differently from the second coating blocks 32B. Thus, the present invention mitigates the warpage of the chip body 10 through implementing the first coating blocks 32A and the second coating blocks 32B of different insulating materials, different thicknesses, and different shapes.

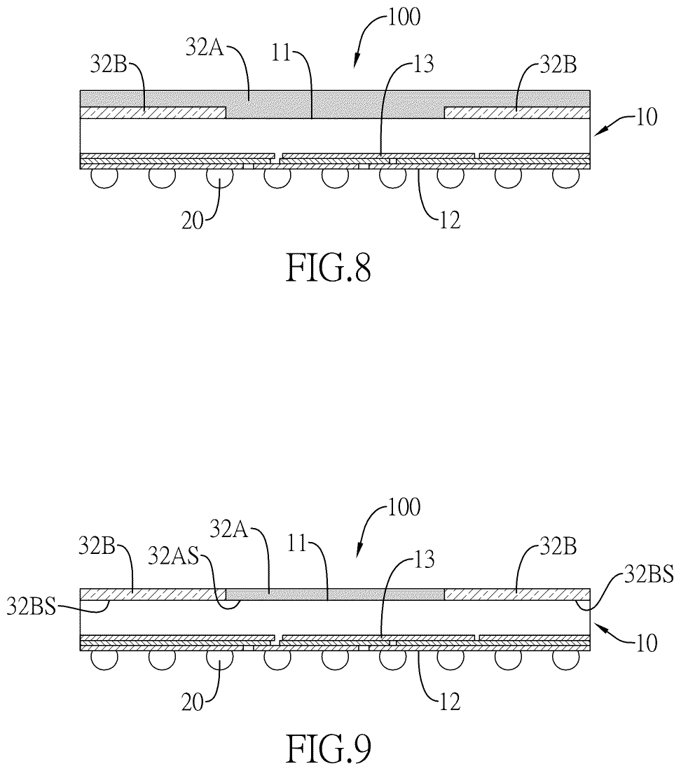

With reference to FIG. 8, in a fifth embodiment of the present invention, the anti-warpage layer 30 is made from various different insulating materials. More particularly, a plurality of second coating blocks 32B are placed at the corners of the back surface 11, and a first coating block 32A covers each of the second coating blocks 32B as well as the rest of areas on the back surface 11. The second coating blocks 32B are made of a second insulating material, and the first coating block 32A is made of a first insulating material. In the present embodiment, the first coating block 32A is made of epoxy mold compound (EMC). Furthermore, side surfaces of the first coating block 32A, side surfaces of the second coating blocks 32B, and side surfaces of the chip body 10 are aligned. However, the side surfaces of the first coating block 32A and the side surfaces of the second coating blocks 32B do not cover the side surfaces of the chip body 10.

With reference to FIG. 9, in a sixth embodiment of the present invention, in comparison to the fifth embodiment as shown in FIG. 8, the first coating block 32A, made of EMC, only covers other areas on the back surface 11 apart from the plurality of second coating blocks 32B. In other words, the second coating blocks 32B are exposed. Moreover, the first coating block 32A has a first surface 32AS and each of the second coating blocks 32B has a second surface 32BS, and the first surface 32AS of the first coating block 32A and the second surfaces 32BS of the second coating blocks 32B are coplanar to the back surface 11. The first surface 32AS of the first coating block 32A and the second surfaces 32BS of the second coating blocks 32B are aligned with each other.

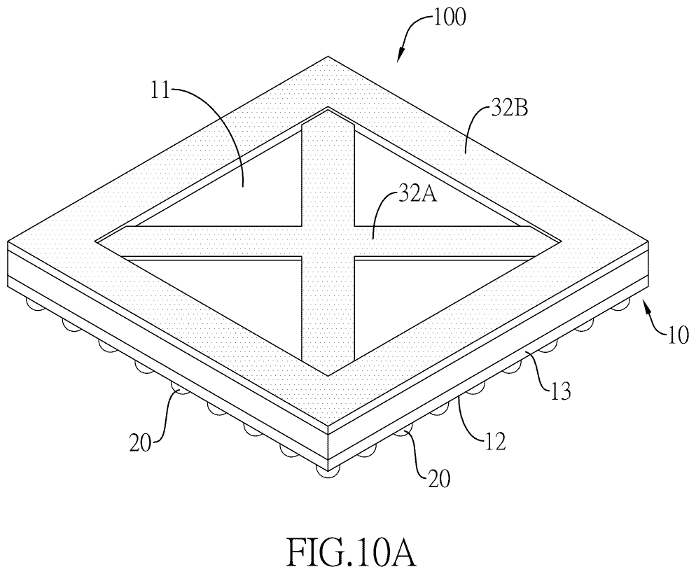

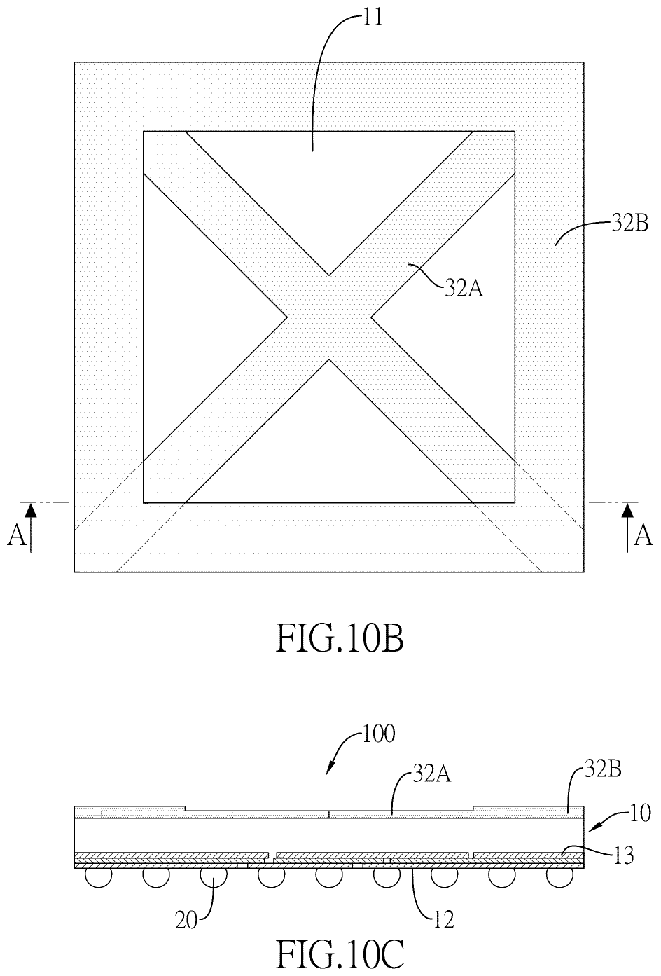

With reference to FIG. 10A, FIG. 10B, and FIG. 10C, in a seventh embodiment of the present invention, a first coating block 32A covers two diagonal lines of the back surface 11 of the chip body 10, and thus the first coating block 32A is formed as an “X” shape on the back surface 11. A second coating block 32B is formed along the edges of the back surface 11, and the second coating block 32B partially covers the first coating block 32A. More particularly, FIG. 10C presents a cross-sectional perspective view of the chip body that is diced and then viewed from an A-A direction as shown in FIG. 10B. As shown in FIG. 10C, at parts where the first coating block 32A and the second coating block 32B overlap, an overall thickness of the coated insulating material is greater. In other words, as the second coating block 32B partially covers the first coating block 32A, an overall thickness of the second coating block 32B is greater than an overall thickness of parts of the first coating block 32A that are exposed. In the present embodiment, the first coating block 32A and the second coating block 32B are made of same materials. In other embodiments, the first coating block 32A and the second coating block 32B are made from various different insulating materials.

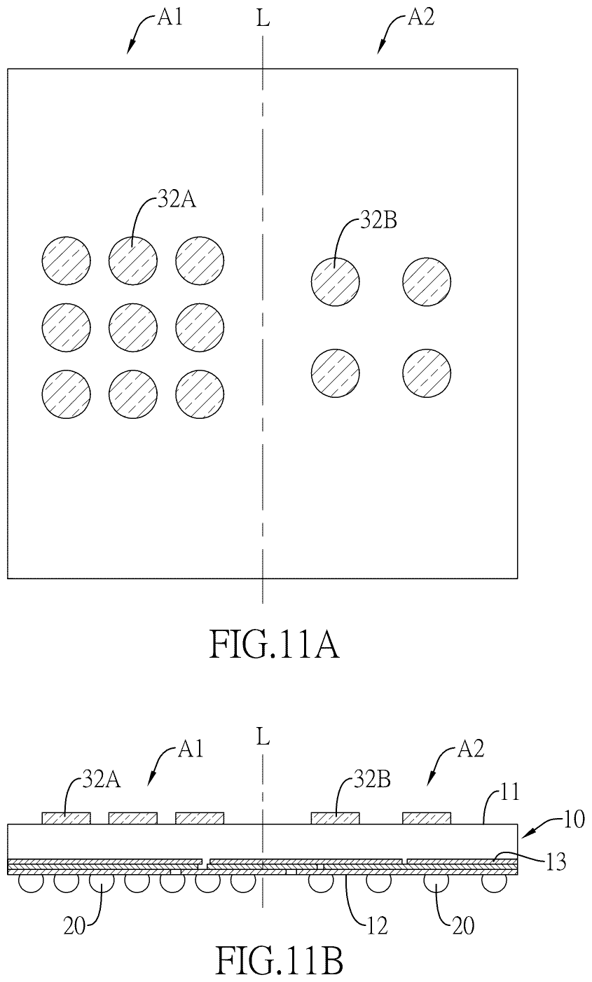

With reference to FIG. 11A and FIG. 11B, in an eighth embodiment of the present invention, a bisector line L equally divides the back surface 11 of the chip body 10 into a first area A1 and a second area A2, i.e., the first area A1 and the second area A2 are of the same size. The chip body 10 has a higher density of arrays of signal contacts 20 in the first area A1, and relatively, the chip body 10 has a lower density of arrays of signal contacts 20 in the second area A2. Since the arrays of signal contacts 20 have different densities in the first area A1 and the second area A2, i.e. a number of the signal contacts in the first area A1 is greater than a number of the signal contacts 20 in the second area A2, the present embodiment asymmetrically places a plurality of first coating blocks 32A in the first area A1 and a plurality of second coating blocks 32B in the second area A2 along two sides of the bisector line L. As a result, a total overall insulating area covered by all of the first coating blocks 32A in the first area A1 is greater than a total overall insulating area covered by all of the second coating blocks 32B in the second area A2. Because the arrays of signal contacts 20 are placed with different densities and different numbers across different areas on the active surface 12 of the chip body 10, the chip body 10 might develop various warpage magnitudes at different locations. To mitigate such a warpage problem, the present embodiment finely adjusts a covering area size of the anti-warpage layer 30 over the back surface 11 of the chip body 10, thus adequately decreasing the warpage magnitudes across different locations of the chip body 10.

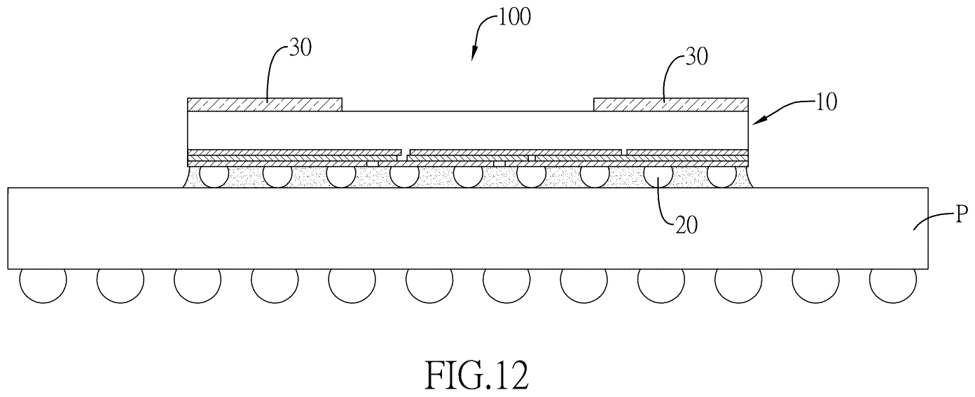

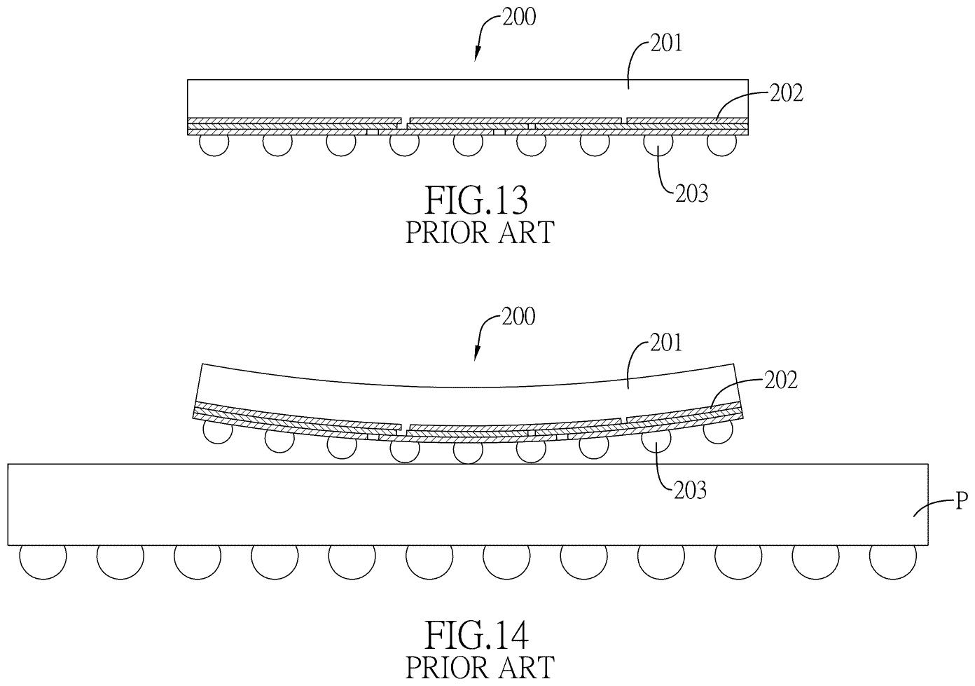

With reference to FIG. 12, a packaging structure of the present invention is shown. A low warpage chip 100, as previously mentioned in any of the embodiments, may be mounted onto a surface of a board P by a way of flip chip. The signal contacts 20 of the low warpage chip 100 are electrically connected to the surface of the board P, thus forming a flip chip packaging structure. Please note that in an embodiment, the board P is a circuit board. In other embodiments, the board P may also be a carrier or a substrate. As flip chip includes a thermal processing procedure, the present invention has prepared a counter-measure to mitigate a warpage development caused by the thermal processing procedure. More particularly, since the anti-warpage layer 30 is mounted on the back surface 11 of the chip body 10 in the present invention, and since a thermal expansion coefficient of the anti-warpage layer 30 is greater than a thermal expansion coefficient of the chip body 10, the anti-warpage layer 30 is able to expand more than the chip body 10 when the anti-warpage layer 30 and the chip body 10 are both heated, thus maintaining the chip body 10 in a relatively flat state and mitigate the warpage problem. As a result, with the warpage problem mitigated, an overall height of the low warpage chip 100 may be more easily controlled and managed, and additionally, the low warpage chip 100 is less likely to disconnect from the board P due to warpage, and thus the present invention is able to better ensure a stable connection between the low warpage chip 100 and the board P.

What is claimed is:

1. A low warpage chip, comprising:
a chip body, comprising a back surface, an active surface, and a plurality of side surfaces; wherein the back surface and the active surface are facing opposite directions, and each of the side surfaces is connected between the back surface and the active surface;
a plurality of signal contacts, mounted on the active surface of the chip body; and
an anti-warpage layer, covering at least a part of the back surface, and without extending to the plurality of side surfaces of the chip body; wherein the anti-warpage layer is made of an insulating material;
wherein a thermal expansion coefficient of the anti-warpage layer is greater than a thermal expansion coefficient of the chip body.

2. The low warpage chip as claimed in claim 1, wherein the anti-warpage layer comprises a plurality of coating blocks, and the plurality of coating blocks are placed on the back surface of the chip body.

3. The low warpage chip as claimed in claim 2, wherein the plurality of coating blocks comprises at least one first coating block and a plurality of second coating blocks;
wherein the at least one first coating block and the plurality of second coating blocks are made from different materials, thus the at least one first coating block and the plurality of second coating blocks have different thermal expansion coefficients.

4. The low warpage chip as claimed in claim 3, wherein the plurality of second coating blocks are placed across different locations on the back surface of the chip body;
wherein the first coating block covers each of the second coating blocks and also covers the back surface of the chip body.

5. The low warpage chip as claimed in claim 3, wherein the plurality of second coating blocks are placed across different locations on the back surface of the chip body;
wherein the at least one first coating block only covers other areas on the back surface of the chip body apart from the plurality of second coating blocks;
wherein the at least one first coating block each has a first surface and each of the second coating blocks has a second surface; the first surface and the second surfaces are coplanar to the back surface of the chip body; and the first surface and the second surfaces are aligned with each other.

6. The low warpage chip as claimed in claim 2, wherein the plurality of coating blocks comprises a plurality of first coating blocks and a plurality of second coating blocks;
wherein a thickness of the plurality of first coating blocks and a thickness of the plurality of second coating blocks are different on the back surface of the chip body.

7. The low warpage chip as claimed in claim 2, wherein the plurality of coating blocks comprises a plurality of first coating blocks and a plurality of second coating blocks;
wherein the plurality of second coating blocks partially cover the plurality of first coating blocks on the back surface of the chip body.

8. The low warpage chip as claimed in claim 2, wherein the plurality of coating blocks comprises a plurality of first coating blocks and a plurality of second coating blocks;
wherein the plurality of first coating blocks have different shapes from the plurality of second coating blocks.

9. The low warpage chip as claimed in claim 2, wherein the plurality of coating blocks comprises a plurality of first coating blocks and a plurality of second coating blocks;
wherein a bisector line divides the back surface of the chip body into two equally-sized areas, and the plurality of first coating blocks and the plurality of second coating blocks are symmetrically placed along two sides of the bisector line.

10. The low warpage chip as claimed in claim 2, wherein the plurality of coating blocks comprises a plurality of first coating blocks and a plurality of second coating blocks;
wherein a bisector line divides the back surface of the chip body into two equally-sized areas, and the plurality of first coating blocks and the plurality of second coating blocks are asymmetrically placed along two sides of the bisector line.

11. The low warpage chip as claimed in claim 10, wherein the bisector line divides the back surface of the chip body into a first area and a second area;
wherein a number of the signal contacts in the first area is greater than a number of the signal contacts in the second area;
wherein the plurality of first coating blocks are placed in the first area, and the plurality of second coating blocks are placed in the second area;
wherein a total overall insulating area covered by all of the first coating blocks in the first area is greater than a total overall insulating area covered by all of the second coating blocks in the second area.

12. The low warpage chip as claimed in claim 2, wherein the back surface of the chip body is divided into a plurality of unit areas of a same size;
wherein parts of the unit areas, away from the edges of the back surface, collectively form a central area of the back surface, and the plurality of coating blocks are placed in the central area.

13. The low warpage chip as claimed in claim 2, wherein the back surface of the chip body is divided into a plurality of unit areas of a same size;
wherein the plurality of coating blocks are placed in parts of the unit areas adjacent to edges of the back surface of the chip body.
